(19) United States
(12) Patent Application Publication
(10) Pub. No.: US 2007/0096229 A1
(43) Pub. Date: May 3, 2007

(54) MAGNETORESISTIVE ELEMENT AND MAGNETIC MEMORY DEVICE

(76) Inventors: Masatoshi Yoshikawa, Yokohama-shi (JP); Toshihiko Nagase, Sagamihara-shi (JP); Eiji Kitagawa, Sagamihara-shi (JP); Hiroaki Yoda, Sagamihara-shi (JP); Tatsuya Kishi, Yokohama-shi (JP); Masahiko Nakayama, Fuchu-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/551,868

(22) Filed: Oct. 23, 2006

(30) Foreign Application Priority Data
Oct. 28, 2005 (JP) 2005-315436

(51) Int. Cl. H01L 43/00

(52) U.S. Cl. 257/421

(57) ABSTRACT

A magnetoresistive element includes a magnetic recording layer which records information as a magnetization direction changes upon supplying a bidirectional current in an out-of-plane direction, a magnetic reference layer which has a fixed magnetization direction, and a nonmagnetic layer which is provided between the magnetic recording layer and the magnetic reference layer. The magnetic recording layer includes an interface magnetic layer which is provided in contact with the nonmagnetic layer and has a first magnetic anisotropy energy, and a magnetic stabilizing layer which has a second magnetic anisotropy energy higher than the first magnetic anisotropy energy.

### CROSS-REFERENCE TO RELATED APPLICATIONS

This application is based upon and claims the benefit of priority from prior Japanese Patent Application No. 2005-315436, filed Oct. 28, 2005, the entire contents of which are incorporated herein by reference.

### BACKGROUND OF THE INVENTION

1. Field of the Invention

The present invention relates to a magnetoresistive element and magnetic memory device and, for example, to a magnetoresistive element capable of recording information by supplying a current bidirectionally and a magnetic memory device using the same.

2. Description of the Related Art

There are recently proposed a number of solid-state memories that record information on the basis of a new principle. Among them all, a magnetoresistive random access memory (MRAM) using a tunneling magnetoresistive (TMR) effect is especially receiving a great deal of attention as a solid-state magnetic memory. As a characteristic feature, an MRAM stores data in accordance with the magnetization state of a magnetic tunnel junction (MTJ) element.

In a field-write-type MRAM, as the size of an MTJ element decreases, a coercive force Hc increases, and therefore, a current necessary for write increases. In fact, to manufacture an MRAM with a large storage capacity (256 Mbits or more), the chip size must be small. For this purpose, it is necessary to decrease the write current while suppressing size reduction of the MTJ element by increasing the cell array occupation ratio in the chip. However, the field-write-type MRAM cannot reduce the cell size for a larger capacity and is inapplicable to the manufacture of an MRAM with a large storage capacity.

To solve this problem, reference 1 (U.S. Pat. No. 6,256,223), reference 2 (C. Slonczewski, “Current-driven excitation of magnetic multilayers”, JOURNAL OF MAGNETISM AND MAGNETIC MATERIALS, VOLUME 159, 1996, pp. L1-L7), and reference 3 (L. Berger, “Emission of spin waves by a magnetic multilayer traversed by a current”, PHYSICAL REVIEW B, VOLUME 54, NUMBER 13, 1996, pp. 9353-9358) propose a spin transfer MRAM using spin injection.

In a spin transfer MRAM, a magnetization switching current density Jc defines a magnetization switching current Ic. Hence, when an element area S decreases, the switching current Ic also decreases. The spin transfer MRAM is expected to have excellent scalability as compared to the field-write-type MRAM. However, the current spin transfer MRAM has a very high current density Jc on the order of 10⁷ A/cm².

In a spin transfer MRAM using a TMR film, hence, the tunnel barrier layer reaches a breakdown voltage Vbd and causes dielectric breakdown before obtaining a desired current density. Additionally, no operational reliability at a high voltage is ensured even without dielectric breakdown.

The switching current by spin injection is proportional to the volume of the recording layer. Hence, the magnetization switching current density is proportional to the thickness of the recording layer. As is generally known, the more the thickness increases, the larger the switching current becomes. On the other hand, to hold information recorded in the recording layer, its volume must generally be equal to or more than a desired value in consideration of the influence of heat (called thermal agitation).

An energy required to hold recorded information without magnetization switching by thermal agitation is defined by Ku·V=Ku·S·t (Ku is the magnetic anisotropy energy per unit volume of the recording layer, V is the volume of the recording layer, S is the area of the recording layer, and t is the thickness of the recording layer). “Ku·V” must be equal to or more than a desired value independently of the size. The magnetic anisotropy energy Ku is constant. For these reasons, when the element area decreases, the recording layer must be thick. As a result, the switching current density Jc becomes high.

### BRIEF SUMMARY OF THE INVENTION

According to a first aspect of the present invention, there is provided a magnetoresistive element comprising: a magnetic recording layer which records information as a magnetization direction changes upon supplying a bidirectional current in an out-of-plane direction; a magnetic reference layer which has a fixed magnetization direction; and a nonmagnetic layer which is provided between the magnetic recording layer and the magnetic reference layer. The magnetic recording layer includes an interface magnetic layer which is provided in contact with the nonmagnetic layer and has a first magnetic anisotropy energy, and a magnetic stabilizing layer which has a second magnetic anisotropy energy higher than the first magnetic anisotropy energy.

According to a second aspect of the present invention, there is provided a magnetoresistive element comprising: a laminated structure including a first magnetic reference layer, a first nonmagnetic layer, a magnetic recording layer, a second nonmagnetic layer, and a second magnetic reference layer which are sequentially stacked, the first magnetic reference layer having a fixed magnetization direction, the magnetic recording layer recording information as a magnetization direction changes upon supplying a bidirectional current in an out-of-plane direction, and the second magnetic reference layer having a fixed magnetization direction. The magnetic recording layer includes a first interface magnetic layer and a second interface magnetic layer which are provided in contact with the first nonmagnetic layer and the second nonmagnetic layer and have a first magnetic anisotropy energy and a second magnetic anisotropy energy, respectively, and a magnetic stabilizing layer which is provided between the first interface magnetic layer and the second interface magnetic layer and has a third magnetic anisotropy energy higher than the first magnetic anisotropy energy and the second magnetic anisotropy energy.

According to a third aspect of the present invention, there is provided a magnetic memory device comprising a memory cell including the magnetoresistive element and a first electrode and second electrode which supply a current to the magnetoresistive element.

### BRIEF DESCRIPTION OF THE SEVERAL VIEWS OF THE DRAWING

FIG. 1 is a sectional view showing an MR element 10 according to the first embodiment;

FIG. 2 is a sectional view showing another arrangement example of a magnetic recording layer 13;

FIG. 3 is a sectional view showing still another arrangement example of the magnetic recording layer 13;

FIG. 4 is a sectional view showing the phase structure of a magnetic stabilizing layer 15;

FIG. 5 is a sectional view showing another example of the phase structure of the magnetic stabilizing layer 15;

FIG. 6 is a sectional view showing still another example of the phase structure of the magnetic stabilizing layer 15;

FIG. 7 is a sectional view showing another arrangement example of the MR element 10;

FIG. 8 is a sectional view showing still another arrangement example of the MR element 10;

FIG. 9 is a sectional view showing still another arrangement example of the MR element 10;

FIG. 10 is a sectional view showing still another arrangement example of the MR element 10;

FIG. 11 is a sectional view showing still another arrangement example of the MR element 10;

FIG. 12 is a sectional view showing still another arrangement example of the MR element 10;

FIG. 13 is a sectional view showing still another arrangement example of the MR element 10;

FIG. 14 is a sectional view showing still another arrangement example of the MR element 10;

FIG. 15 is a circuit diagram showing an MRAM according to the second embodiment; and

FIG. 16 is a sectional view of the MRAM shown in FIG. 15.

### DETAILED DESCRIPTION OF THE INVENTION

The embodiments of the present invention will be described below with reference to the accompanying drawing. The same reference numerals denote element having the same functions and arrangements in the description, and a repetitive description will be done only if necessary.

(First Embodiment)

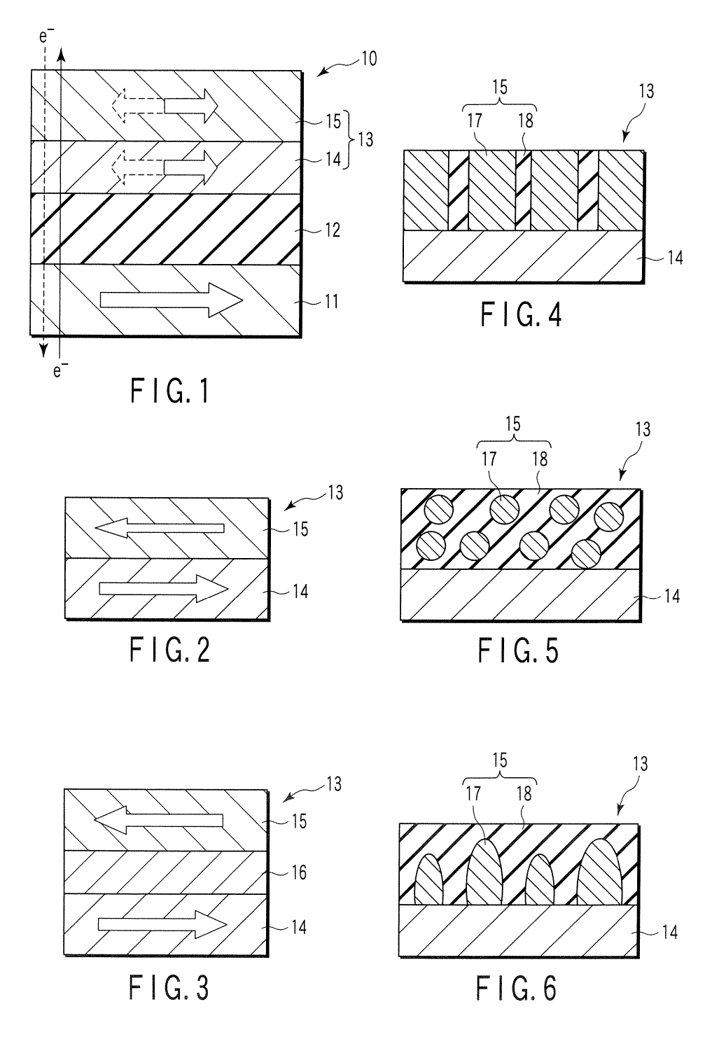

FIG. 1 illustrates the magnetoresistive element (MR element) 10 having, e.g., planar magnetization alignment. Each arrow in the drawings indicates a magnetization direction.

This embodiment uses spin momentum transfer. A bidirectional current in the out-of-plane direction (in the direction perpendicular to the plane) is supplied to the MR element 10 to switch the magnetization of a magnetic recording layer by the function of spin of electrons. That is, the MR element 10 is a spin transfer magnetoresistive element capable of switching magnetization by supplying spin-polarized electrons (spin injection).

The MR element 10 includes a magnetic recording layer (free layer) 13 having a laminated structure of an interface magnetic layer 14 and magnetic stabilizing layer 15, a magnetic reference layer (pinned layer) 11, and a nonmagnetic layer 12 sandwiched between the magnetic recording layer 13 and the magnetic reference layer 11. The magnetization direction of the magnetic recording layer 13 switches. The magnetic reference layer 11 having a fixed magnetization direction is referred to in reading or writing information.

The direction of easy magnetization of the magnetic reference layer 11 and magnetic recording layer 13 is parallel to the film surface. The direction of easy magnetization is a direction that minimizes the internal energy of a certain ferromagnetic material with a macro size when its spontaneous magnetization turns to the direction without any external magnetic field. The direction of hard magnetization is a direction that maximizes the internal energy of a certain ferromagnetic material with a macro size when its spontaneous magnetization turns to the direction without any external magnetic field.

A magnetic material with a low magnetic anisotropy energy has a direction of easy magnetization depending on the shape of the magnetic material. Generally, the in-plane direction tends to be the direction of easy magnetization. A magnetic material to which induced magnetic anisotropy is applicable can decide the direction of easy magnetization to a field application direction by annealing in a magnetic field and film formation in a magnetic field. A material with a high magnetocrystalline anisotropy has the direction of easy magnetization in a crystallographically stable direction. Any magnetic material has a magnetocrystalline anisotropy which is regarded to be high at 5×10⁵ erg/cm² or more.

An operation of writing information in the MR element 10 with the above-described arrangement will be explained from the physical viewpoint. In this embodiment, a current indicates a flow of electrons (e⁻).

Phenomenologically, “1” data is written by supplying a current from the magnetic recording layer 13 to the magnetic reference layer 11, and “0” data is written by supplying a current from the magnetic reference layer 11 to the magnetic recording layer 13.

Referring to FIG. 1, when a current flows to the MR element 10 in the out-of-plane direction from the magnetic reference layer 11 to the magnetic recording layer 13, spin-polarized electrons flow from the magnetic reference layer 11 to the magnetic recording layer 13 due to the spin accumulation effect in the magnetic reference layer 11. In this case, polarized electrons with minority spin in the magnetic reference layer 11 are reflected by the magnetic reference layer 11. Polarized electrons with majority spin in the magnetic reference layer 11 are transmitted through the magnetic reference layer 11 and enter the magnetic recording layer 13.

The electrons with majority spin give a torque to the magnetic moment of the magnetic recording layer 13 and align its magnetization parallel to that of the magnetic reference layer 11. The magnetization direction of the magnetic reference layer 11 becomes parallel to that of the magnetic recording layer 13. The resistance value of the MR element 10 is minimum in this parallel alignment state. This state is defined as “0” data.

On the other hand, when a current flows to the MR element 10 in the out-of-plane direction from the magnetic recording layer 13 to the magnetic reference layer 11, spin-polarized electrons flow from the magnetic recording layer 13 to the magnetic reference layer 11. In this case, electrons with majority spin are transmitted through the magnetic reference layer 11. Electrons with minority spin are reflected by the magnetic reference layer 11 and return to the magnetic recording layer 13 while keeping the spin angular momentum (without changing the spin direction).

The electrons with minority spin give a torque to the magnetic moment of the magnetic recording layer 13 and align its magnetization antiparallel to that of the magnetic reference layer 11. The magnetization direction of the magnetic reference layer 11 becomes antiparallel to that of the magnetic recording layer 13. The resistance value of the MR element 10 is maximum in this antiparallel alignment state. This state is defined as “1” data.

The MR element 10 can record information (“1” data and “0” data) in this way. Information is read out by supplying a read current to the MR element 10 and detecting a change in resistance value of the MR element 10.

Detailed examples of the layers included in the MR element 10 will be described next. First, the arrangement of the nonmagnetic layer 12 will be explained. The nonmagnetic layer 12 can use an insulating material, a metal, or a mixed crystal thereof. An element using an insulating material is a tunneling magnetoresistive (TMR) element using a tunneling magnetoresistive effect. An element using a metal is a current perpendicular to plane (CPP)-giant magnetoresistive (GMR) element. These are collectively called magnetoresistive (MR) elements.

In a TMR element, a tunnel barrier layer serving as a nonmagnetic layer uses AlOₓ, MgO, CaO, EuO, SrO, BeO, MgO/Mg, AlOₓ/Al, TiOₓ, ZrOₓ, HfOₓ, and a laminated film thereof.

Especially, MgO with the highest MR ratio is preferable because it can achieve an MR ratio of 100% or more. MgO that has a very high tunneling probability for only majority spin is a representative oxide material having a spin filter effect. Hence, MgO can exhibit a TMR effect equal to or more than the spin polarizability of the magnetic recording layer 13 and magnetic reference layer 11. MgO can achieve an MR ratio of 100% or more when the resistance and area (RA) product of the TMR element is 5 to 100 Ωμm². MgO has an NaCl structure. A (001) plane orientation is most preferable from the viewpoint of MR ratio. However, a (110) or (111) plane orientation can also obtain a sufficiently high MR ratio of 100% or more.

Inserting an Mg layer with a thickness of 0.5 nm or less above or under the MgO layer is preferable from the viewpoint of MR ratio improvement. The MR ratio can further improve if Fe—Mg or Co—Mg bonds are dominant on the interface between the magnetic reference layer 11 and the MgO layer or on the interface between the interface magnetic layer 14 and the MgO layer. That is, an interface magnetic layer element hardly forms an oxide such as Fe—O, Co—O, Ni—O, Mn—O, or Cr—O on the interface between the magnetic reference layer 11 and the MgO layer or on the interface between the interface magnetic layer 14 and the MgO layer. To suppress deterioration of the TMR effect, the thickness of the inserted Mg layer is preferably a 3-atomic layer or less, i.e., about 0.5 nm or less.

The MgO layer serving as the nonmagnetic layer 12 is formed by sputtering using an MgO target or Mg target. The MgO layer may be formed by reactive sputtering in an O₂ atmosphere. The MgO layer may also be formed by forming an Mg layer and oxidizing it by oxygen radicals, oxygen ions, or ozone. The MgO layer may be epitaxially grown by molecular beam epitaxy (MBE) or electron beam evaporation using MgO.

In epitaxial growth, the orientation of MgO decides the orientation of a magnetic layer serving as an underlayer to be selected. The magnetic layer serving as an underlayer preferably has a bcc (body-centered cubic) structure (001), fcc (face-centered cubic) structure (111), and bcc structure (110) in correspondence with MgO (001), MgO (111), and MgO (110). The bcc structure is preferably made of Fe, Fe₁₀₀₋ₓCoₓ (0<x<70, at %), Co with the thickness of 1-nm or less, or a Co alloy material. The bcc structure may be made of Fe-rich Fe₁₀₀(CoNi)₁₀₀₋ₓ (0≦x<50, at %).

When the magnetic reference layer 11 uses a 3-nm thick Co₄₀Fe₂₀B₂₀ (at %) layer, the nonmagnetic layer 12 uses a 1-nm thick MgO (001) layer, and the interface magnetic layer 14 uses a 1-nm thick Co₄₀Fe₄₀B₂₀ (at %) layer, a TMR element having an RA product of 10 Ωμm² and an MR ratio of 150% is obtained. More specifically, the TMR film structure is Ta5/Co₄₀Fe₄₀B₂₀3/MgO0.75/Mg0.4/Co₄₀Fe₄₀B₂₀3/Ru0.85/Co₉₀Fe₁₀2.5/PtMn15/Ta5//substrate.

To obtain an MRAM using spin injection magnetization switching, a magnetization switching current density Jc is preferably lower than 1×10⁶ A/cm² because of the relationship between the withstand voltage and the MR ratio. Since the withstand voltage of MgO is about 1 V, the actual magnetization switching voltage must be 1 V or less. If the RA product is 2 to 100 Ωμm² (both inclusive), the MgO barrier film can ensure an MR ratio of 100% or more, i.e., an MR ratio that poses no problem for circuit operation. It is therefore essential that the upper value is 1 V, and the RA product is 100 Ωμm² or less. As a result, it is necessary to ensure the current density Jc of 1×10⁶ A/cm².

To achieve the RA product is 100 Ωμm² or less with the nonmagnetic layer 12 using MgO, the thickness of the MgO layer must be 1.5 nm or less. To set the RA product to 10 Ωμm² or less, the MgO layer must have a thickness of 1 nm or less.

The arrangement of the magnetic recording layer 13 will be described next. The magnetization direction of the magnetic recording layer 13 switches due to the spin injection effect or spin accumulation effect by an externally supplied current. The magnetic recording layer 13 includes the interface magnetic layer 14 and magnetic stabilizing layer 15.

The interface magnetic layer 14 and magnetic stabilizing layer 15 ferromagnetically or antiferromagnetically exchange-couple with each other so that the magnetic recording layer 13 can have parallel alignment or antiparallel alignment at a portion adjacent to the nonmagnetic layer 12 with respect to the magnetic reference layer 11. The interface magnetic layer 14 and magnetic stabilizing layer 15 exchange-couple with each other and therefore function as one magnetic layer. In the magnetic recording layer 13 shown in FIG. 1, the interface magnetic layer 14 and magnetic stabilizing layer 15 ferromagnetically exchange-couple with each other in a stable parallel alignment state.

FIGS. 2 and 3 show the magnetic recording layer 13 that is parallel to the magnetic reference layer 11 while the interface magnetic layer 14 and magnetic stabilizing layer 15 ferromagnetically and antiferromagnetically exchange-couple with each other. Referring to FIGS. 2 and 3, the magnetic reference layer 11 and nonmagnetic layer 12 have the same arrangements as in FIG. 1. FIGS. 2 and 3 illustrate only the magnetic recording layer 13 of the MR element 10.

To obtain the antiferromagnetic alignment state in FIG. 2, the magnetic stabilizing layer 15 uses a ferrimagnetic material. To obtain the antiferromagnetic alignment state in FIG. 3, a nonmagnetic layer 16 is formed on the interface magnetic layer 14, and the magnetic stabilizing layer 15 is formed on the nonmagnetic layer 16. In this case, the interface magnetic layer 14 and magnetic stabilizing layer 15 antiferromagnetically exchange-couple with each other through the nonmagnetic layer 16. The nonmagnetic layer 16 can use, for example, Ru or Os.

As shown in FIGS. 2 and 3, the antiferromagnetic alignment state of the magnetic recording layer 13 cancels the saturation magnetization of the upper and lower layers. Hence, the apparent saturation magnetization amount in the residual magnetization state decreases, and the thermal stability and stability to an external magnetic field improve.

The magnetic recording layer 13 includes the interface magnetic layer 14 and magnetic stabilizing layer 15. The interface magnetic layer 14 has a higher polarizability or smaller damping constant α than the magnetic stabilizing layer 15. The polarizability and damping constant will be described later in detail. In this case, the spin torque generated by current supply to the MR element preferentially intensively acts on the interface magnetic layer 14. More specifically, precession of magnetization of the interface magnetic layer 14 causes precession of magnetization of the entire magnetic recording layer 13. To attain magnetization switching by causing the interface magnetic layer 14 to excite precession, design of the magnetic anisotropy energies and thicknesses of the interface magnetic layer 14 and magnetic stabilizing layer 15 is important. Material design to ensure them is also important.

The interface magnetic layer 14 has a lower magnetic anisotropy energy than the magnetic stabilizing layer 15. Since the magnetic anisotropy energy of the interface magnetic layer 14 is low, its damping constant is also small. Hence, the damping constant is also smaller in the interface magnetic layer 14 than in the magnetic stabilizing layer 15. The damping constant is obtained quantitatively by ferro-magnetic-resonance (FMR) measurement. The damping constant is expressed by “α”. The damping constant α of the interface magnetic layer 14 is preferably 0.05 or less. A material mainly containing Fe can suppress the damping constant to 0.01 or less. This is because the damping constant of Fe is as small as 0.002. On the other hand, the magnetic stabilizing layer 15 having a high magnetic anisotropy energy has a damping constant of 0.1 or more. The magnetic anisotropy energy is here regarded to be high at about 5×10⁶ erg/cm² or more.

The interface magnetic layer 14 is mainly arranged to obtain the magnetoresistive effect. Hence, the interface magnetic layer 14 preferably has a high bulk polarizability of the material and a high interface polarizability to the nonmagnetic layer 12. The interface magnetic layer 14 having a high polarizability can contribute improvement of the MR ratio. It is therefore possible to accurately read out information from the MR element 10 even when the read current decreases.

The thickness of the interface magnetic layer 14 needs to be 0.5 nm (inclusive) to 5 nm (exclusive). If thinner than 0.5 nm, it is impossible to obtain a sufficient material magnetic characteristic and crystallinity of the interface magnetic layer 14 and a sufficient MR ratio. At 5 nm or more, a current Ic necessary for magnetization switching largely increases, and magnetization switching may be impossible at a voltage equal to or lower than the breakdown voltage of the tunnel barrier layer.

Two detailed examples (1) and (2) of the material of the interface magnetic layer 14 will be described below. The interface magnetic layer 14 uses a magnetic material having a high polarizability. The polarizability of the interface magnetic layer 14 is obtained by Andrew reflection measurement or spectroscopy using X-ray magnetic circular dichroism (XMCD).

(1) Ferromagnetic materials containing Fe, Co, Ni, Mn, or Cr.

Detailed examples are a bcc-CoFe alloy or bcc-CoFeNi alloy such as Fe₅₀Co₅₀ (at %) having a high bulk polarizability of 0.3 or more, an fcc-CoFe alloy or fcc-CoFeNi alloy such as Co₉₀Fe₁₀ (at %) having a high polarizability, and an amorphous CoFe alloy or amorphous CoFeNi alloy such as (bcc-Co_{0.5}Fe_{0.5})₈₀B20 (at %) having a high polarizability.

A bcc-CoFe alloy or bcc-CoFeNi alloy can adjust the damping constant to 0.01 or less by adjusting the composition. In this case, the Fe content must be 30 at % or more. However, (bcc-CoFe)₈₀B₂₀ (at %) can achieve a damping constant of 0.01 or less when the Fe content of the Fe/Co composition ratio is 30 at % or more although the material has an amorphous structure.

(2) Mn-based ferromagnetic alloy, Mn-based ferromagnetic Heusler alloy, Cr-based ferromagnetic alloy, and oxide half-metal such as Fe₂O₃.

An Mn-based ferromagnetic Heusler alloy is a body-centered cubic system alloy represented by A₂MnX having an ordered lattice. Examples of the “A” “element are Cu, Au, Pd, Ni, and Co. Examples of the “X” element are Al, In, Sn, Ga, Ge, Sb, and Si. Examples of an Mn-based ferromagnetic alloy are an MnAl alloy, MnAu alloy, MnZn alloy, MnGa alloy, MnIr alloy, MnPt₃ alloy. As a characteristic feature, these alloys have an ordered lattice. An example of a Cr-based ferromagnetic alloy is a CrPt₃ alloy which also has an ordered lattice. A half-metal indicates a ferromagnetic material in which electron spin in an electronic state at the Fermi level is 100% biased to one direction (only majority spin is present). An Mn-based ferromagnetic Heusler alloy can have a very small damping constant because it uses Mn. The damping constant of Mn as a single substance is theoretically 0.

The interface layer having ferromagnetism can also use FeRhX (X=Ir, Pt, or Pd) that causes magnetic transition from an antiferromagnetic state (AF) to a ferromagnetic state (FM). An FeRhX alloy has no Ms in the AF state and exhibits Ms in the FM state. The FeRhX alloy causes phase transition from the AF state to the FM state at a certain temperature. In the read mode at a low voltage, the MR element is in the AF state because the heat value is small, and write access by spin injection is impossible. In the write mode at a high voltage, the MR element changes to the FM state because the heat value increases, and write access by spin injection is possible.

The interface magnetic layer 14 contacts the nonmagnetic layer 12. The interface magnetic layer 14 has a saturation magnetization Msf1 and magnetic anisotropy energy Kaf1. The interface magnetic layer 14 has the magnetic stabilizing layer 15 on the surface opposite to the contact surface to the nonmagnetic layer 12.

The interface magnetic layer 14 exchange-couples with the magnetic stabilizing layer 15. The exchange coupling energy can range from 0.05 erg/cm² (inclusive) to 1.0 erg/cm² (exclusive). At an energy lower than 0.05 erg/cm², magnetization rotation by spin injection magnetization switching does not occur in synchronism in the interface magnetic layer 14 and magnetic stabilizing layer 15. That is, exchange coupling is actually lost due to, e.g., the influence of heat so that the magnetizations of the layers may rotate almost separately.

The magnetic stabilizing layer 15 has a saturation magnetization Msf2 and high magnetic anisotropy energy Kaf2. When the magnetic recording layer 13 has the magnetic stabilizing layer 15 with the high magnetic anisotropy energy Kaf2, the thermal stability of the magnetic recording layer 13 improves. The magnetic anisotropy energy of the magnetic stabilizing layer 15 must be higher than that of the interface magnetic layer 14.

Hence, the relationship between the magnetic anisotropy energies Kaf1 and Kaf2 is given by
Kaf1<Kaf2
The relationship between the saturation magnetizations Msf1 and Msf2 preferably satisfies
Msf1≧Msf2

That is, an anisotropy magnetic field Ha is given by
Ha=2·Ka/Ms
For this reason, an anisotropy magnetic field Hkf1 of the interface magnetic layer 14 is smaller than an anisotropy magnetic field Hkf2 of the magnetic stabilizing layer 15. The anisotropy magnetic field Ha can generally be measured by an M-H curve or R-H curve in the direction of hard axis of the MR element 10.

The product (Msf·tf) of a saturation magnetization Msf and thickness tf of the magnetic recording layer 13 is preferably 3.0×10⁴ emu/cm² or less. This is because the present embodiment aims at a spin transfer MRAM with a large storage capacity by using the MR element 10 having a short side length of 100 nm or less, for which the magnetization switching current Ic by spin injection must be 0.1 mA or less. The restriction of the write current comes from the transistor size. When the minimum feature size (F) is 100 nm or less, it is difficult to drive a current larger than 0.1 mA.

From the viewpoint of saturation magnetization Ms, the saturation magnetization Msf of the magnetic recording layer 13 is preferably 600 emu/cc or less. This is based on the restriction of the switching current Ic of 0.1 mA or less.

In spin injection magnetization switching, the magnetic recording layer 13 has a thickness (characteristic length) for effective spin torque. This characteristic length is decided by a length (spin diffusion length) to conduct electrons while maintaining spin information and a length (decoherence length) to rotate spin and magnetization by precession almost one revolution.

The thickness tf of the magnetic recording layer 13 is preferably 10 nm or less because of the restriction of spin diffusion length. The thickness tf of the magnetic recording layer 13 is more preferably 5 nm or less in consideration of the restriction of precession of magnetization and the spin torque amount damping effect. Also considering the restriction of the interface magnetic layer 14 based on the above-described restriction of MR ratio, the thickness tf of the magnetic recording layer 13 satisfies 1 nm≦tf≦10 nm, and preferably, 1 nm≦tf≦5 nm. At this time, a thickness tf2 of the magnetic stabilizing layer 15 satisfies 0.5 nm≦tf2≦9.5 nm, and preferably, 0.5 nm≦tf2≦4.5 nm. A magnetic stabilizing layer having a thickness of 0.5 nm less can exhibit no effective magnetic anisotropy energy.

The thickness ratio of the interface magnetic layer 14 to the magnetic recording layer 13 is preferably 1/20 to 1/2 (both inclusive). This is based on the fact that the thickness of the interface magnetic layer 14 to obtain a sufficient MR ratio is 0.5 nm. When the magnetic recording layer 13 is 10 nm thick, the thickness ratio is 1/20. When the magnetic recording layer 13 is 2 nm thick, the thickness ratio is 1/2. The thickness is 2 nm when taking the lower limit value of the thickness to obtain thermal stability into consideration.

When the magnetic recording layer has perpendicular magnetization while the interface magnetic layer has in-plane magnetization, and the magnetic stabilizing layer has perpendicular magnetization, the thickness of the interface magnetic layer is preferably 3 nm or less. In this case, Msf and Kaf of the entire magnetic recording layer must satisfy
Kaf−4πMsf²>0

To obtain thermal stability and information holding stability, the magnetic anisotropy energy Kaf2 of the magnetic stabilizing layer 15 needs to be 5×10⁵ erg/cc or more. This is an empirical magnetic anisotropy energy Ka necessary for holding information recorded in the magnetic recording layer 13 for 10 years or more. Hence, the magnetic anisotropy energy Ka is preferably higher than it.

Especially when the magnetic anisotropy energy Kaf1 of the interface magnetic layer 14 is low, and the anisotropy magnetic field Hkf1 is smaller than 50 Oe, the magnetic anisotropy energy Kaf2 of the magnetic stabilizing layer 15 is preferably 1×10⁶ erg/cc or more, and the saturation magnetization Msf2 is preferably 400 emu/cc or less. At this time, the anisotropy magnetic field Hkf2 of the magnetic stabilizing layer 15 is Hkf2=2·Kaf2/Msf2=5000 Oe or more. To use perpendicular magnetization in the magnetic recording layer 13 and thermally stabilize it, the magnetic anisotropy energy Kaf2 of the magnetic stabilizing layer 15 is preferably 1×10⁶ erg/cc or more. At this time, the anisotropy magnetic field Hkf2 is 1 kOe or more.

From the viewpoint of reduction of the switching current, it is preferable to set the thicknesses of the interface magnetic layer 14 and magnetic stabilizing layer 15 such that the coercive force of the magnetic recording layer 13 becomes 1 kOe or less. As described above, to form a spin transfer MRAM with a large storage capacity, an area Af of the magnetic recording layer 13 is preferably 0.005 μm² or less. Under these conditions, the size of the magnetic recording layer 13 is 0.1×0.05 μm² at an aspect ratio of 2 and almost 0.07×0.07 μm² at an aspect ratio of 1.

At this time, to prevent the switching current from varying, it is actually necessary to prevent the magnetization switching field from varying. Statistically examining, the magnetic characteristics of crystal grains do not even out unless the number of crystal grains of the magnetic recording layer 13 is at least about 100 per bit. This causes variations in magnetization switching of multiple bits when a cell array is formed.

Considering this, the crystal grain size is preferably 5 nm or less. From this viewpoint, at least one of the interface magnetic layer 14 and magnetic stabilizing layer 15 preferably has an amorphous phase. It is more preferable that the interface magnetic layer 14 should have an amorphous phase because control of the crystal grain is easier. It is preferable to use amorphous (CoFe)₁₀₀₋ₓBₓ (15<x<50, at %) or amorphous (NiFe)₁₀₀₋ₓBₓ (15<x<50, at %).

However, this does not apply to a perpendicular magnetization MR element using a high magnetocrystalline anisotropy. In the perpendicular magnetization MR element, the magnetic anisotropy almost aligns in the vertical direction. Hence, the perpendicular magnetization MR element has relatively small magnetic anisotropy dispersion as compared to an in-plane magnetization film that obtains an in-plane magnetic anisotropy by using shape magnetic anisotropy and magnetocrystalline anisotropy. Actually, in a perpendicular magnetization film having an hcp (hexagonal closest packing) structure, the crystal orientation of the (001) plane serves as an important index of magnetic anisotropy dispersion. The peak of the half-width of the locking curve in the hcp structure (001) is held at almost 5° or less. It is therefore possible to form a film having very small anisotropy dispersion, considering that magnetic anisotropy dispersion is almost equivalent to crystal orientation dispersion.

Three detailed examples (1) to (3) of the material of the magnetic stabilizing layer 15 will be described below.

(1) Ferrimagnetic materials containing at least one of Fe, Co, Ni, Mn, Cr, and rare-earth elements.

The rare-earth elements include La, Ce, Pr, Nd, Pm, Sm, Eu, Gd, Tb, Dy, Ho, Er, Tm, Yb, Lu, Ac, Th, Pa, U, Np, Pu, Am, Cm, Bk, Cf, Es, Fm, Md, No, and Lr. In this embodiment, Ho, Dy, Er, Nd, Gd, Sm, Tb, and Eu are particularly effective. A ferrimagnetic material containing a rare-earth element has an amorphous structure. The ferrimagnetic material can have a low saturation magnetization of 400 emu/cc or less and a high magnetic anisotropy energy of about 1×10⁶ erg/cc by adjusting the composition. Some amorphous alloys containing a rare-earth element having a 3d element and 4f electron exhibit ferrimagnetism. These alloys readily cause perpendicular magnetization and are usable as a perpendicular magnetization film. Examples of amorphous materials having ferrimagnetism are CoFe—Tb and CoFe—Gd. CoFe—Tb has a high magnetic anisotropy energy and large spin-orbit interaction, the damping constant α is as large as 0.1 or more. However, an addition of Gd, Ho, or Dy can decrease the damping constant α.

A ferrimagnetic material has a composition point (composition compensation point) where the net Ms is 0 and can easily reduce Ms. A CoFe-RE (RE: rare-earth) alloy has a compensation point in the RE composition range of 15 to 40 at %. Since Ms² influences the magnetization switching current, Ms reduction is preferable for current reduction.

(2) Ferromagnetic materials containing at least one of Fe, Co, Ni, Mn, and Cr and at least one element selected from Pt, Pd, Ir, Rh, Re, Os, Au, Ag, Cu, B, C, Si, Al, Mg, Ta, Cr, Zr, Ti, V, Hf, Y, Sr, Ba, Sc, Ca, and rare-earth elements.

The rare-earth elements include La, Ce, Pr, Nd, Pm, Sm, Eu, Gd, Tb, Dy, Ho, Er, Tm, Yb, Lu, Ac, Th, Pa, U, Np, Pu, Am, Cm, Bk, Cf, Es, Fm, Md, No, and Lr. In this embodiment, Ho, Dy, Er, Nd, Gd, Sm, Tb, and Eu are particularly effective.

Representative materials of the magnetic stabilizing layer 15 are a CoCrPt alloy, CoCrTa alloy, and CoCrPtTa alloy having an hcp structure. The materials can have a magnetic anisotropy energy of 1×10⁶ erg/cc or more.

In terms of a high magnetic anisotropy energy, an ordered Fe_{50±10}Pt_{50±10} (at %) alloy having an L1₀ structure is preferable. FePt changes from an fcc structure to an fct structure after ordering. Since the axis of anisotropy runs along the [001] direction, the priority plane orientation is preferably (001). In this case, a FePt alloy has perpendicular magnetization.

(3) Ferromagnetic materials containing mixed crystal of metal magnetic phase and insulating phase.

The metal magnetic phase of the magnetic stabilizing layer 15 is made of a ferromagnetic material containing at least one of Fe, Co, Ni, Mn, and Cr and at least one of Pt, Pd, Ir, Rh, Re, Os, Au, Ag, Cu, Ta, and rare-earth elements. The insulating phase of the magnetic stabilizing layer 15 is made of an oxide, nitride, or oxynitride containing at least one element selected from B, C, Si, Al, Mg, Ta, Cr, Zr, Ti, V, Hf, Y, Sr, Ba, Sc, Ca, and rare-earth elements. The rare-earth elements include La, Ce, Pr, Nd, Pm, Sm, Eu, Gd, Tb, Dy, Ho, Er, Tm, Yb, Lu, Ac, Th, Pa, U, Np, Pu, Am, Cm, Bk, Cf, Es, Fm, Md, No, and Lr. In this embodiment, Ho, Dy, Er, Nd, Gd, Sm, Tb, and Eu are particularly effective.

FIGS. 4 to 6 are sectional views for explaining the phase structure of the magnetic stabilizing layer 15. As described above, the magnetic stabilizing layer 15 is made of a ferromagnetic material containing a mixed crystal of a metal magnetic phase 17 and an insulating phase 18.

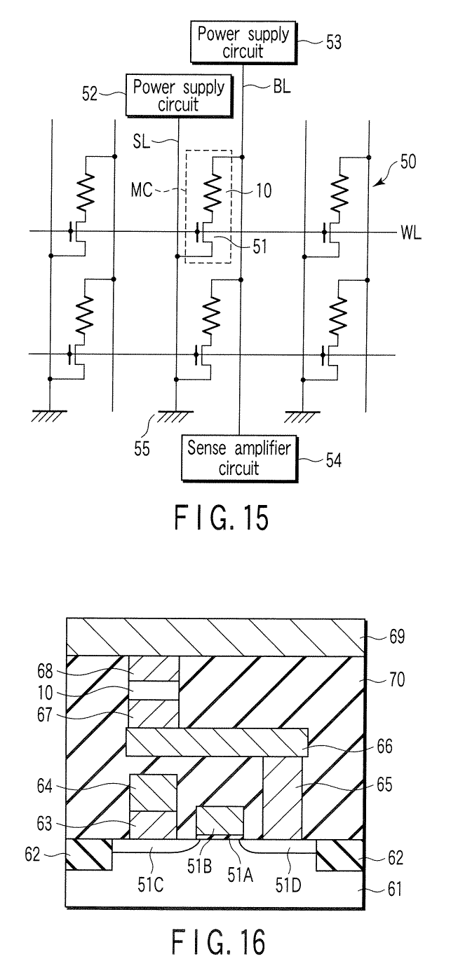

In FIG. 4, the magnetic stabilizing layer 15 is separated into an insulating phases 18 and a plurality of metal magnetic phases 17 grown to a columnar shape and having a high magnetic anisotropy energy. Since a current concentrates to the metal magnetic phases 17, the current density increases, and the substantial switching current becomes small. The magnetic stabilizing layers 15 shown in FIGS. 15 and 16 also have the same effect. The magnetic stabilizing layer 15 shown in FIG. 5 has a granular structure with a plurality of grain-shaped metal magnetic phases 17 in an insulating phase 18. The magnetic stabilizing layer 15 shown in FIG. 6 has an island grown structure having, in an insulating phase 18, a plurality of metal magnetic phases 17 grown upward from the interface magnetic layer 14.

Referring to FIGS. 5 and 6, since the current flows through a path with the smallest tunnel barrier, a current constriction effect is obtained, as in FIG. 4. In addition, electrons reflected by elastic scattering between the insulating phase 18 and the interface magnetic layer 14 and between the insulating phase 18 and metal magnetic phase 17 assist magnetization switching.

The ratio of the metal magnetic phase 17 to the insulating phase 18 depends on the volume and the degree of current constriction of the magnetic stabilizing layer 15 necessary for obtaining thermal agitation resistance. To sufficiently enhance the current constriction effect, the ratio of the metal magnetic phase 17 to the insulating phase 18 is preferably 0.5 or less. This is equivalent to an area ratio of 50% or less. Hence, the current density can be twice or more. As a result, it is possible to design a device capable of obtaining a current density enough for switching the portion having a high magnetic anisotropy energy.

The above-described columnar crystal grain, granular crystal grain, and island grown crystal grain have an appropriate grain size dispersion. When the short side length of the TMR element is 100 nm or less, microcrystallization is necessary. If 100 grains must be present in the TMR element to even out a variation between elements, the crystal grain must be about 1/10 the short side length of the element. If the short side length of the element is 100 nm, the crystal grain must be 10 nm or less. If the short side length of the element is 70 nm, the crystal grain must be 7 nm or less. If the short side length of the element is 45 nm, the crystal grain must be about 5 nm or less.

Consider a case wherein exchange coupling between crystal grains is not completely lost. Even small crystal grains exist which have a low apparent magnetocrystalline anisotropy energy. Hence, these crystal grains form a region that readily switches due to spin injection. Upon spin injection or magnetic field application, the crystal grains serve as a nucleus, and the magnetic recording layer causes magnetization switching at a small current or magnetic field.

On the other hand, since the crystal grains exchange-couple, crystal grains having a high magnetocrystalline anisotropy energy decide the thermal stability of the magnetic recording layer. Hence, the thermal stability is high. Generally, if such a phenomenon occurs, a coercive force Hcf, anisotropy magnetic field Hkf (or saturation magnetic field Hsf), the anisotropy energy Kaf, and the saturation magnetization Msf of the magnetic recording layer 13 of the TMR element satisfy
Hcf<2·Kaf/Msf
Hcf<Hsf (or Hkf)
as is empirically found. When the above relationships hold, the magnetic recording layer can do spin injection magnetization switching at a low current density.

The above-described columnar crystal structure, granular crystal structure, and island grown crystal structure can easily disperse the magnetocrystalline anisotropy energy of each crystal grain. Generally, no spin-transfer torque acts when the relative angle of magnetization is 0° and 180°. To cause magnetization switching, it is necessary to thermally activate the magnetic recording layer by using heat generated by supplying a large current. Hence, spin injection magnetization switching requires a large current.

However, if the magnetic recording layer has an appropriate magnetocrystalline anisotropy energy dispersion, spin injection magnetization switching occurs at a low current. The degree of magnetocrystalline anisotropy energy dispersion is in close relation to crystal orientation dispersion. When the crystal orientation dispersion is 5° to 45° (both inclusive), spin injection magnetization switching occurs at a low current as compared to a case wherein dispersion rarely exists. The crystal orientation dispersion is more preferably 5° to 15° (both inclusive).

In a Co alloy having an hcp structure or an FePt alloy having an fct (face-centered tetragonal) structure, spin injection magnetization switching can occur at a low current when the C-axis orientation or (001) plane orientation is controlled in the above range. The crystal orientation dispersion is effective in a spin transfer MR element including a magnetic recording layer and magnetic reference layer with an in-plane magnetic anisotropy or perpendicular magnetic anisotropy.

The magnetic reference layer 11 will be described next. The magnetic reference layer 11 having a uniaxial magnetic anisotropy or unidirectional magnetic anisotropy stabilizes in a predetermined magnetization direction. The magnetic reference layer 11 includes an interface magnetic layer made of a material with a high bulk polarizability and high surface polarizability on the interface to the nonmagnetic layer 12.

The magnetic reference layer 11 includes a laminated film of an interface magnetic layer that has a saturation magnetization Msp1 and magnetic anisotropy energy Kap1 and is in contact with the nonmagnetic layer 12, and a magnetic stabilizing layer that has a saturation magnetization Msp2 and magnetic anisotropy energy Kap2. The magnetic anisotropy energies Kap1 and Kap2 are preferably 1×10⁶ erg/cm² or more.

A product (Mps·tp) of a saturation magnetization Msp and thickness tp of the magnetic reference layer 11 is preferably larger than the product (Mpf·tf) of the saturation magnetization Msf and thickness tf of the magnetic recording layer 13.

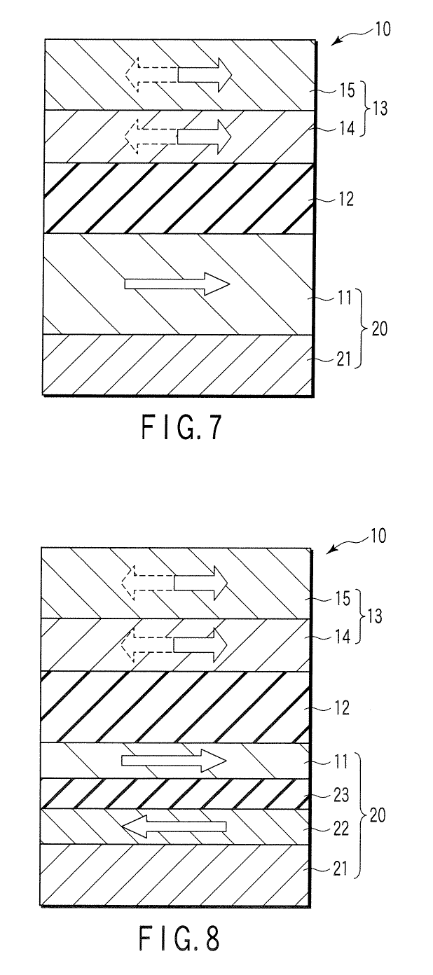

Other detailed arrangement examples of the spin transfer MR element 10 will be described next with reference to FIGS. 7 to 14.

Referring to FIG. 7, a magnetic reference layer 20 includes the magnetic reference layer 11 and an antiferromagnetic layer 21. The magnetization of the magnetic reference layer 20 is fixed in one direction by using exchange coupling of the antiferromagnetic layer 21 and ferromagnetic layer (magnetic reference layer 11). This layer will be called a magnetization fixing monolayer.

Referring to FIG. 8, the magnetic reference layer 20 has a synthetic antiferromagnetic (SAF) structure including the magnetic reference layer 11, nonmagnetic layer 23, magnetization fixing layer 22, and antiferromagnetic layer 21. The order of the layers included in the magnetic reference layer 20 is the order from the upper side. This also applies to the following description of a laminated structure.

The SAF structure is formed by stacking two ferromagnetic layers with reverse magnetization directions while inserting a nonmagnetic layer therebetween. In the SAF structure, the magnetic fields of the two ferromagnetic layers form a loop. Hence, the magnetic fields do not leak and influence the peripheral cells. In addition, the exchange-coupled ferromagnetic layers have an improved thermal agitation resistance as an effect of the increased volume.

Referring to FIG. 8, the magnetization fixing layer 22 exchange-couples with the antiferromagnetic layer 21 and therefore has a magnetization fixed in one direction. The magnetic reference layer 11 antiferromagnetically exchange-couples with the magnetization fixing layer 22 and therefore has a magnetization fixed in one direction.

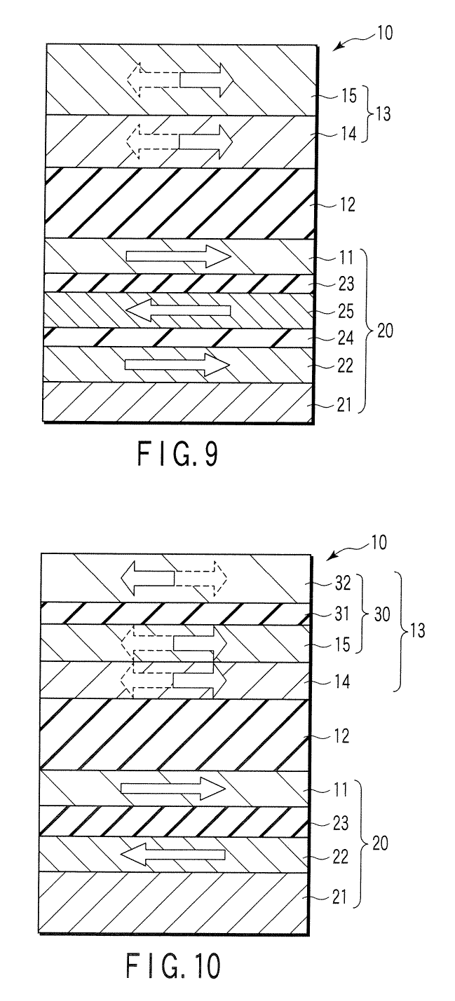

Referring to FIG. 9, the magnetic reference layer 20 has a laminated structure including the magnetic reference layer 11, nonmagnetic layer 23, intermediate magnetic layer 25, nonmagnetic layer 24, magnetization fixing layer 22, and antiferromagnetic layer 21. The magnetic reference layer 20 with this structure has an improved thermal stability. That is, the sum of Ku·V (product of magnetic anisotropy energy and volume) of magnetic layers on the upper and lower sides of a nonmagnetic layer decides the thermal stability of an SAF structure. Hence, the thermal stability further improves in use of three magnetic layers and two nonmagnetic layers.

Referring to FIG. 10, the magnetic recording layer 13 has a laminated structure of a second magnetic stabilizing layer 32, nonmagnetic layer 31, first magnetic stabilizing layer 15, and interface magnetic layer 14. Of this structure, a magnetic stabilizing layer 30 has an SAF structure including the second magnetic stabilizing layer 32, nonmagnetic layer 31, and first magnetic stabilizing layer 15. The magnetic recording layer 13 has a laminated structure of the magnetic stabilizing layer 30 and interface magnetic layer 14.

Referring to FIG. 10, the sum of Ku·V (product of magnetic anisotropy energy and volume) of magnetic layers on the upper and lower sides of a nonmagnetic layer decides the thermal stability of the magnetic recording layer 13. Ku·V also defines the thermal stability of a magnetic recording layer having no SAF structure. In an SAF structure, magnetic layers on the upper and lower sides of a nonmagnetic layer magnetostatically couple with each other. This cancels a magnetization with a reverse sign at the ends of the magnetic layers so that end magnetic domains formed at the ends of the magnetic layers disappear. As a result, the magnetic layers on the upper and lower sides of the nonmagnetic layer integrate, and the thermal stability of the magnetic recording layer 13 improves.

Since an external magnetic field resistance caused by the end magnetic domains and the effect of demagnetizing fields at the ends of the magnetic layers decrease, the magnetic and thermal stability of the entire magnetic recording layer improve. In this case, Mr·t (product of residual magnetization and thickness) of the magnetic layers formed on the upper and lower sides of the nonmagnetic layer are adjusted so that the absolute values of magnetization almost equal. Ideally, the absolute values preferably almost equal but actually have a slight shift in consideration of a problem of fabrication. However, a shift of Mr·t influences the magnetic field distribution. Hence, the shift amount is preferably 1 nmT (nanometer tesla) or less in terms of Mr·t.

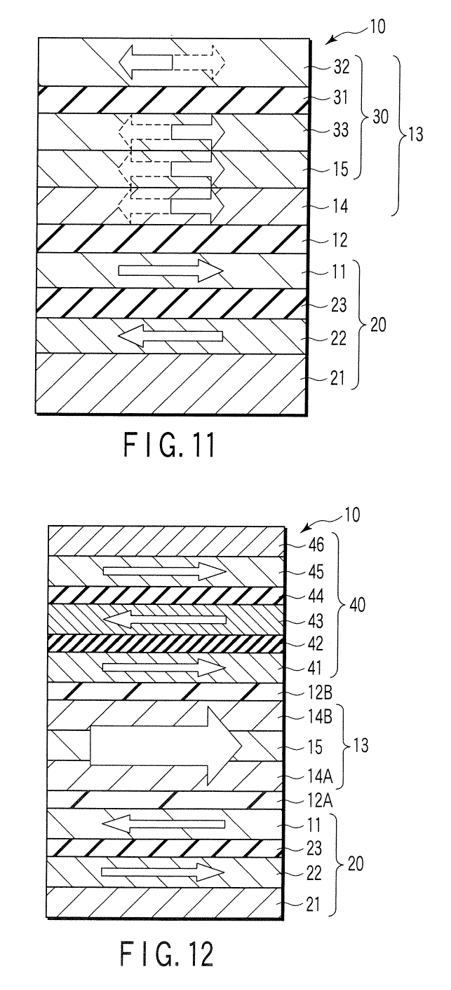

Referring to FIG. 11, the magnetic recording layer 13 has an SAF structure including the second magnetic stabilizing layer 32, nonmagnetic layer 31, coupled magnetic layer 33, first magnetic stabilizing layer 15, and interface magnetic layer 14. The coupled magnetic layer 33 assists antiferromagnetic exchange coupling between the first magnetic stabilizing layer 15 and the second magnetic stabilizing layer 32 through the nonmagnetic layer 31. Insertion of the coupled magnetic layer 33 strengthens the antiferromagnetic coupling of the second magnetic stabilizing layer 32, nonmagnetic layer 31, and coupled magnetic layer 33. This can completely integrate the motions of magnetizations of the magnetic layers on the upper and lower sides of the nonmagnetic layer 31, i.e., the magnetization switching behaviors in the magnetic recording layer 13, resulting in an improved thermal stability. Hence, the coupled magnetic layer 33 is made of, e.g., a CoFe alloy that firmly couples with Ru or Os.

Use of the magnetic recording layer having the SAF structure with antiferromagnetic exchange coupling enables to apparently reduce the residual magnetization amount, i.e., the product Mr·t of a residual magnetization Mr and thickness t of the magnetic recording layer 13. This ensures the thermal stability and improves the external magnetic field resistance. Referring to FIG. 2, the apparent saturation magnetization amount Mr·t in the residual magnetization state is given by
Mr·t=|Mrf1·tf1−Mrf2·tf2|
where tf1 is the thickness of the interface magnetic layer 14, tf2 is the thickness of the magnetic stabilizing layer 15, Mrf1 is the residual magnetization of the interface magnetic layer 14, and Mrf2 is the residual magnetization of the magnetic stabilizing layer 15.

The MR element 10 shown in FIG. 12 has a so-called dual-pin structure having two magnetic reference layers 20 and 40 having magnetizations fixed in different directions. The magnetic reference layer 40 has a laminated structure of an antiferromagnetic layer 46, magnetization fixing layer 45, nonmagnetic layer 44, intermediate magnetic layer 43, nonmagnetic layer 42, and magnetic reference layer 41. The magnetic recording layer 13 has a laminated structure of a second interface magnetic layer 14B, magnetic stabilizing layer 15, and first interface magnetic layer 14A. A first nonmagnetic layer 12A is inserted between the magnetic recording layer 13 and the magnetic reference layer 20. A second nonmagnetic layer 12B is inserted between the magnetic recording layer 13 and the magnetic reference layer 40.

In this arrangement, supply of a current in the out-of-plane direction reduces the switching current because the spin injection effect and spin accumulation effect are available simultaneously. In the dual-pin structure, the magnetic reference layers 20 and 40 have magnetizations in reverse directions. For this reason, the current density necessary for magnetization switching of the magnetic recording layer 13 does not depend on the current direction, and “0” data and “1” data can be written with the same current value. Hence, the write circuit can be simple.

Even the MR element 10 having the dual-pin structure sets the magnetic anisotropy energy of the magnetic stabilizing layer 15 to be larger than that of the first interface magnetic layer 14A. The MR element 10 also sets the damping constant of the magnetic stabilizing layer 15 to be larger than that of the first interface magnetic layer 14A. The damping constant of the magnetic stabilizing layer 15 is 0.1 or more. The damping constant of the first interface magnetic layer 14A is preferably 0.05 or less. Similarly, the MR element 10 sets the magnetic anisotropy energy of the magnetic stabilizing layer 15 to be larger than that of the second interface magnetic layer 14B. The MR element 10 also sets the damping constant of the magnetic stabilizing layer 15 to be larger than that of the second interface magnetic layer 14B. The damping constant of the second interface magnetic layer 14B is preferably 0.05 or less. The magnetic anisotropy energy of the first interface magnetic layer 14A may equal to or different from that of the second interface magnetic layer 14B as long as they satisfy the above-described conditions. This also applies to the MR elements 10 with a dual-pin structure to be described later.

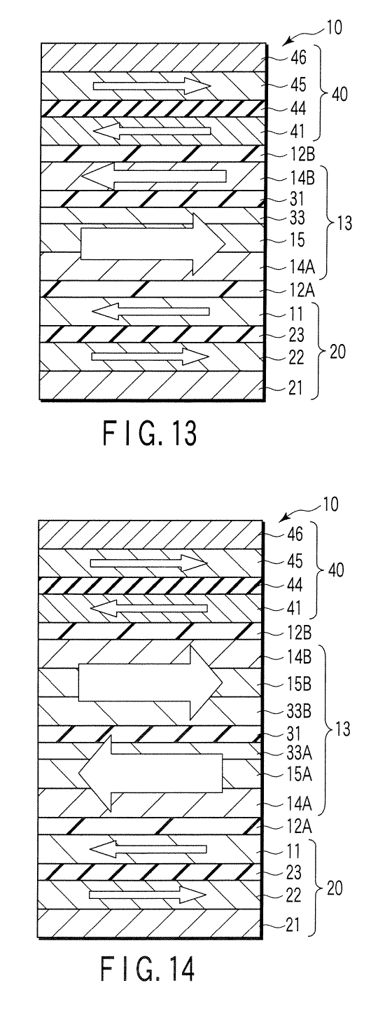

Each of the MR elements 10 shown in FIGS. 13 and 14 has the two magnetic reference layers 20 and 40 with magnetizations fixed in the same direction. Each of the magnetic reference layers 20 and 40 has an SAF structure. The magnetic recording layer 13 also has an SAF structure. In FIG. 13, the structure including the coupled magnetic layer 33, magnetic stabilizing layer 15, and first interface magnetic layer 14A is defined as a first magnetic recording layer. The second interface magnetic layer 14B is defined as a second magnetic recording layer. Similarly in FIG. 14, the structure including a first coupled magnetic layer 33A, first magnetic stabilizing layer 15A, and first interface magnetic layer 14A is defined as a first magnetic recording layer. The structure including the second interface magnetic layer 14B, second magnetic stabilizing layer 15B, and second coupled magnetic layer 33B is defined as a second magnetic recording layer.

In these arrangements, the direction of magnetic field application in annealing uniquely decides the magnetization directions of the magnetization fixing layers 22 and 45 in the same direction. This also decides the magnetization directions of the magnetic reference layers 11 and 41 in the same direction.

On the other hand, the magnetic recording layer 13 also has the SAF structure, though the magnetic layers on the upper and lower sides of the nonmagnetic layer 31 have antiparallel magnetizations. Hence, if the magnetization direction of the first magnetic recording layer is parallel to that of the magnetic reference layer 20, the magnetization direction of the second magnetic recording layer is antiparallel to that of the magnetic reference layer 40. That is, use of the magnetic recording layer 13 with the SAF structure forms two, antiparallel and parallel states as in FIG. 12 with respect to one magnetization direction of the dual-pin layer. Hence, supply of a current in the out-of-plane direction reduces the switching current because the spin injection effect and spin accumulation effect are available simultaneously.

### EXAMPLES

A plurality of examples of the MR element 10 will be described below. First, the size and manufacturing method of the MR element 10 used as examples will be described.

An MR element 10 is formed between a lower electrode layer and an upper electrode layer. More specifically, an MTJ film is formed on the lower electrode layer by, e.g., DC magnetron sputtering. The lower electrode layer uses, e.g., Ta. The MTJ film is patterned to a size of about 0.1×0.15 μm² by photolithography using an excimer laser. At this time, a magnetic recording layer 13 has an aspect ratio (long axis/short axis) of 1.5. Then, the MR element 10 is fabricated by ion beam etching (IBE).

An interlayer insulating layer is formed next. The interlayer insulating layer is planarized by chemical mechanical polishing (CMP) to expose the upper surface of the MR element 10. An upper electrode layer is formed on the MR element 10. The upper electrode layer uses, e.g., Ta. Barrier formation conditions are adjusted such that the MR element 10 has a resistance R=5 kΩ in terms of element resistance. The RA product of the MR element 10 is set to about 15 Ωμm².

The electric characteristic and magnetization switching characteristic of a thus formed MRAM were evaluated. Table 1 shows the layer structures of MR elements 10 of Comparative Example and Examples 1 to 8. A numerical value added to each layer represents a thickness. The unit of thickness is nm.

TABLE 1

| | |
|---|---|
| Comparative Example | Ta5/NiFe6/CoFe0.5/AlOₓ0.5/CoFe2.2/ |
| | Ru1/CoFe2.4/PtMn15/Ta5 |
| Example 1 | Ta5/CoCrPt2.5/a-FeCoB0.5/MgO0.8/ |
| | a-FeCoB2.2/Ru1/FeCo2.5/PtMn15/Ta5 |
| Example 2 | Ta5/CoCrPt4.5/a-FeCoB0.5/MgO0.8/ |
| | a-FeCoB2.2/Ru1/FeCo2.5/PtMn15/Ta5 |
| Example 3 | Ta5/CoCrPt9.5/a-FeCoB0.5/MgO0.8/ |
| | a-FeCoB2.2/Ru1/FeCo2.5/PtMn15/Ta5 |
| Example 4 | Ta5/CoCrPt19.5/a-FeCoB0.5/MgO0.8/ |
| | a-FeCoB2.2/Ru1/FeCo2.5/PtMn15/Ta5 |
| Example 5 | Ta5/Cu/CoCrTa4.5/a-FeCo0.5/MgO0.8/ |
| | a-FeCoB2.2/Ru1/FeCo2.5/PtMn15/Ta5 |
| Example 6 | Ta5/Cu/CoCrPtTa—SiO₂4.5/a-FeCoB0.5/ |
| | MgO0.8/a-FeCoB2.2/Ru1/FeCo2.5/PtMn15/Ta5 |
| Example 7 | Ta5/Pt5/FeCoTb4.5/a-FeCoB0.5/MgO0.8/ |
| | a-FeCoB2.2/Ru1/FeCo2.5/PtMn15/Ta5 |
| Example 8 | Ta5/Pt5/FeCoGd4.5/a-FeCoB0.5/MgO0.8/ |
| | a-FeCoB2.2/Ru1/FeCo2.5/PtMn15/Ta5 |

In Table 1, the MR elements 10 of Examples 1 to 8 have the laminated structure shown in FIG. 8. In Table 1, a Ta layer corresponds to the upper or lower electrode layer. An a-FeCoB layer corresponding to an interface magnetic layer 14 or magnetic reference layer 11 is an amorphous layer with a composition of Fe₄₀Co₄₀B₂₀ (at %). The MR elements 10 underwent annealing at 380° C. MgO corresponding to a nonmagnetic layer 12 had a (001) plane orientation after this annealing.

The composition of CoCrPt corresponding to a magnetic stabilizing layer 15 was Co₇₂Cr₂₀Pt₈ (at %). The composition of CoCrTa was Co₇₆Cr₂₀Ta₄ (at %). The compositions of FeCoTb and FeCoGd were Fe₄₀Co₄₀Tb₂₀ (at %) and Fe₄₀Co₄₀Gd₂₀ (at %), respectively.

A switching current density Jc and MR ratio of each of the MR elements 10 were measured. Table 2 shows the measurement result. Jc(P-to-AP) in Table 2 indicates the switching current density Jc when the magnetization directions of the magnetic reference layer 11 and magnetic recording layer 13 change from the parallel state (P) to the antiparallel state (AP). On the other hand, Jc(AP-to-P) in Table 2 indicates the switching current density Jc when the magnetization directions of the magnetic reference layer 11 and magnetic recording layer 13 change from the antiparallel state (AP) to the parallel state (P).

TABLE 2

| | Jc(P-to-AP) | Jc(AP-to-P) | MR ratio |
|---|---|---|---|
| | (10⁷ A/cm²) | (10⁷ A/cm²) | (%) |
| Comparative | 2.5 | 1.2 | 41 |
| Example | | | |
| Example 1 | 0.092 | 0.048 | 153 |
| Example 2 | 0.097 | 0.050 | 155 |
| Example 3 | 0.097 | 0.050 | 150 |
| Example 4 | 0.210 | 0.120 | 148 |
| Example 5 | 0.097 | 0.050 | 157 |
| Example 6 | 0.080 | 0.043 | 160 |
| Example 7 | 0.091 | 0.050 | 148 |
| Example 8 | 0.088 | 0.051 | 145 |

As shown in Table 2, the switching current density Jc of each example largely decreases as compared to a comparative example. The MR ratio of each example also greatly improves.

As described above in detail, according to this embodiment, since the magnetic recording layer 13 has the magnetic stabilizing layer 15 with a high magnetic anisotropy energy, the thermal stability of the magnetic recording layer 13 can stabilize. In addition, the switching current density can largely decrease as the actual thickness decreases without lowering the thermal agitation resistance.

The magnetic recording layer 13 has the interface magnetic layer 14 with a high polarizability. The interface magnetic layer 14 with the high polarizability can contribute to improvement of the MR ratio of the MR element 10. Hence, even when the read current is small, it is possible to accurately read out information from the MR element 10.

In this embodiment, the layers included in the MR element 10 have in-plane magnetization alignment. However, the present invention is not limited to this. The layers may have perpendicular magnetization alignment. When the magnetocrystalline anisotropy dispersion of the magnetic stabilizing layer 15 is large, and the magnetocrystalline anisotropy in the
axis of a Co alloy having, e.g., a hcp structure is used as a magnetic anisotropy, the magnetic recording layer 13 forms a single magnetic domain to improve the spin injection efficiency in use of perpendicular magnetization alignment. Hence, the substantial switching current density can be reduced.
   (Second Embodiment)

In the second embodiment, an MRAM is formed by using the MR element 10 described above.

As shown in FIG. 15, the MRAM shown FIG. 1 comprises a memory cell array 50 having a plurality of memory cells MC arranged in a matrix. In the memory cell array 50, a plurality of bit lines BL are arranged. The bit lines BL extend the column direction. In the memory cell array 50, a plurality of word lines WL are arranged. The word lines WL extend the row direction.

The intersections of the bit lines BL and word lines WL have the above-described memory cells MC. Each memory cell MC includes the MR element 10 and a select transistor 51. One terminal of each MR element 10 connects to the bit line BL. The other terminal of the MR element 10 connects to the drain of the select transistor 51. The word line WL connects to the gate of the select transistor 51. The source of the select transistor 51 connects to a source line SL.

A power supply circuit 53 connects to one end of the bit line BL. A sense amplifier circuit 54 connects to the other end of the bit line BL. A power supply circuit 52 connects to one end of the source line SL. A power supply 55 connects to the other end of the source line SL through a switching element (not shown).

The power supply circuit 53 applies a positive potential to one end of the bit line BL. The sense amplifier circuit 54 detects the resistance value of the MR element 10 and also applies, e.g., a ground potential to the other end of the bit line BL. The power supply circuit 52 applies a positive potential to one end of the source line SL. The power supply 55 turns on the switching element connected to it, thereby applying, e.g., a ground potential to the other end of the source line SL. Each power supply circuit includes a switching element to control electrical connection to a corresponding wiring layer.

Data write in the memory cell MC is done in the following way. First, to select the memory cell MC as a data write target, the word line WL connected to the memory cell MC is activated. This turns on the select transistor 51.

A bidirectional write current Iw is supplied to the MR element 10. More specifically, to supply the write current Iw to the MR element 10 from the upper side to the lower side, the power supply circuit 53 applies a positive potential to one end of the bit line BL. The power supply 55 turns on a switching element corresponding to it to apply a ground potential to the other end of the source line SL.

To supply the write current Iw to the MR element 10 from the lower side to the upper side, the power supply circuit 52 applies a positive potential to one end of the source line SL. The sense amplifier circuit 54 applies a ground potential to the other end of the bit line BL. The switching element corresponding to the power supply 55 is OFF. In this way, “0” data or “1” data is written in the memory cell MC.

Data read from the memory cell MC is done in the following way. First, the memory cell MC is selected. The power supply circuit 52 and sense amplifier circuit 54 supply, to the MR element 10, a read current Ir flowing from the power supply circuit 52 to the sense amplifier circuit 54. The sense amplifier circuit 54 detects the resistance value of the MR element 10 on the basis of the read current Ir. In this way, information stored in the MR element 10 can be read out.

The structure of the MRAM will be described next. FIG. 16 is a sectional view of the MRAM. FIG. 16 shows a portion of the MRAM corresponding to one memory cell MC.

The select transistor 51 serving as a switching element is formed on a p-type semiconductor substrate 61 (or a p-type well provided in a substrate). The p-type semiconductor substrate 61 has a shallow trench isolation (STI) 62 to electrically disconnect the select transistor 51 from neighboring elements.

The select transistor 51 includes, e.g., an NMOS transistor. More specifically, a gate insulating film 51A is formed on the semiconductor substrate 61. A gate electrode 51B is provided on the gate insulating film 51A. The gate electrode 51B corresponds to the word line WL shown in FIG. 15. A source region 51C and a drain region 51D heavily doped with an N⁺-type impurity are provided on both sides of the gate electrode 51B in the semiconductor substrate 61.

A wiring layer 64 is formed on a contact plug 63 on the source region SiC. The wiring layer 64 corresponds to the source line SL shown in FIG. 15. A wiring layer 66 is formed on a contact plug 65 on the drain region 51D. The wiring layer 66 electrically connects the MR element 10 to the drain region 51D.

A lower electrode layer 67 is provided on the wiring layer 66. The lower electrode layer 67 uses, e.g., Ta. The MR element 10 is provided on the lower electrode layer 67. An upper electrode layer 68 is provided on the MR element 10. The upper electrode layer 68 uses, e.g., Ta.

A wiring layer 69 is provided on the upper electrode layer 68. The wiring layer 69 corresponds to the bit line BL shown in FIG. 15. An interlayer insulating layer 70 fills the space between the semiconductor substrate 61 and the wiring layer 69.

As described above, a spin transfer MRAM can be formed by using the MR element 10 of the first embodiment. We confirmed the operation of the spin transfer MRAM shown in FIG. 15 and that a current drivable by the transistor could cause magnetization switching in the MR element 10. A bit yield of 99.9% or more was obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetoresistive element comprising:
a magnetic recording layer which records information as a magnetization direction changes upon supplying a bidirectional current in an out-of-plane direction;
a magnetic reference layer which has a fixed magnetization direction; and
a nonmagnetic layer which is provided between the magnetic recording layer and the magnetic reference layer,
the magnetic recording layer including:
an interface magnetic layer which is provided in contact with the nonmagnetic layer and has a first magnetic anisotropy energy; and
a magnetic stabilizing layer which has a second magnetic anisotropy energy higher than the first magnetic anisotropy energy.

2. The element according to claim 1, wherein the magnetic stabilizing layer is formed of a ferrimagnetic material containing at least one of Fe, Co, Ni, Mn, Cr, and a rare-earth element.

3. The element according to claim 1, wherein the magnetic stabilizing layer is formed of a ferromagnetic material containing at least one of Fe, Co, Ni, Mn, and Cr and at least one of Pt, Pd, Ir, Rh, Re, Os, Au, Ag, Cu, B, C, Si, Al, Mg, Ta, Cr, Zr, Ti, V, Hf, Y, Sr, Ba, Sc, Ca, and a rare-earth element.

4. The element according to claim 1, wherein
the magnetic stabilizing layer is formed of a ferromagnetic material containing a mixed crystal of a metal magnetic phase and an insulating phase,
the metal magnetic phase is formed of a ferromagnetic material containing at least one of Fe, Co, Ni, Mn, and Cr and at least one of Pt, Pd, Ir, Rh, Re, Os, Au, Ag, Cu, Ta, and a rare-earth element, and
the insulating phase is formed of an oxide, a nitride, or an oxynitride containing at least one of B, C, Si, Al, Mg, Ta, Cr, Zr, Ti, V, Hf, Y, Sr, Ba, Sc, Ca, and a rare-earth element.

5. The element according to claim 1, wherein the second magnetic anisotropy energy is not less than 5×10⁵ erg/cc.

6. The element according to claim 1, wherein a thickness of the magnetic stabilizing layer ranges from 0.5 nm to 9.5 nm (both inclusive).

7. The element according to claim 1, wherein the interface magnetic layer is formed of a ferromagnetic material containing at least one of Fe, Co, Ni, Mn, and Cr.

8. The element according to claim 7, wherein a thickness of the interface magnetic layer ranges from 0.5 nm (inclusive) to 5 nm (exclusive).

9. The element according to claim 1, wherein a thickness of the magnetic recording layer ranges from 1 nm to 10 nm (both inclusive).

10. A magnetoresistive element comprising
a laminated structure including a first magnetic reference layer, a first nonmagnetic layer, a magnetic recording layer, a second nonmagnetic layer, and a second magnetic reference layer which are sequentially stacked, the first magnetic reference layer having a fixed magnetization direction, the magnetic recording layer recording information as a magnetization direction changes upon supplying a bidirectional current in an out-of-plane direction, and the second magnetic reference layer having a fixed magnetization direction,
the magnetic recording layer including:
a first interface magnetic layer and a second interface magnetic layer which are provided in contact with the first nonmagnetic layer and the second nonmagnetic layer and have a first magnetic anisotropy energy and a second magnetic anisotropy energy, respectively; and
a magnetic stabilizing layer which is provided between the first interface magnetic layer and the second interface magnetic layer and has a third magnetic anisotropy energy higher than the first magnetic anisotropy energy and the second magnetic anisotropy energy.

11. The element according to claim 10, wherein
the magnetic stabilizing layer and the first interface magnetic layer exchange-couple with each other and have one of a ferromagnetic alignment and an antiferromagnetic alignment, and
the magnetic stabilizing layer and the second interface magnetic layer exchange-couple with each other and have one of a ferromagnetic alignment and an antiferromagnetic alignment.

12. The element according to claim 10, wherein the third magnetic anisotropy energy is not less than 5×10⁵ erg/cc.

13. The element according to claim 10, wherein the magnetic stabilizing layer is formed of a ferrimagnetic material containing at least one of Fe, Co, Ni, Mn, Cr, and a rare-earth element.

14. The element according to claim 10, wherein the magnetic stabilizing layer is formed of a ferromagnetic material containing at least one of Fe, Co, Ni, Mn, and Cr and at least one of Pt, Pd, Ir, Rh, Re, Os, Au, Ag, Cu, B, C, Si, Al, Mg, Ta, Cr, Zr, Ti, V, Hf, Y, Sr, Ba, Sc, Ca, and a rare-earth element.

15. The element according to claim 10, wherein
the magnetic stabilizing layer is formed of a ferromagnetic material containing a mixed crystal of a metal magnetic phase and an insulating phase,
the metal magnetic phase is formed of a ferromagnetic material containing at least one of Fe, Co, Ni, Mn, and Cr and at least one of Pt, Pd, Ir, Rh, Re, Os, Au, Ag, Cu, Ta, and a rare-earth element, and
the insulating phase is formed of an oxide, a nitride, or an oxynitride containing at least one of B, C, Si, Al, Mg, Ta, Cr, Zr, Ti, V, Hf, Y, Sr, Ba, Sc, Ca, and a rare-earth element.

16. The element according to claim 10, wherein a thickness of the magnetic stabilizing layer ranges from 0.5 nm to 9.5 nm (both inclusive).

17. The element according to claim 10, wherein the first interface magnetic layer and the second interface magnetic layer are formed of a ferromagnetic material containing at least one of Fe, Co, Ni, Mn, and Cr.

18. The element according to claim 17, wherein
a thickness of the first interface magnetic layer ranges from 0.5 nm (inclusive) to 5 nm (exclusive), and
a thickness of the second interface magnetic layer ranges from 0.5 nm (inclusive) to 5 nm (exclusive).

19. A magnetic memory device comprising a memory cell including a magnetoresistive element and a first electrode and second electrode which supply a current to the magnetoresistive element,
the magnetoresistive element including:
a magnetic recording layer which records information as a magnetization direction changes upon supplying a bidirectional current in an out-of-plane direction;
a magnetic reference layer which has a fixed magnetization direction; and
a nonmagnetic layer which is provided between the magnetic recording layer and the magnetic reference layer,
the magnetic recording layer including:
an interface magnetic layer which is provided in contact with the nonmagnetic layer and has a first magnetic anisotropy energy; and
a magnetic stabilizing layer which has a second magnetic anisotropy energy higher than the first magnetic anisotropy energy.

20. The device according to claim 19, further comprising:
a first wiring layer electrically connected to the first electrode;
a second wiring layer electrically connected to the second electrode; and
a power supply circuit electrically connected the first wiring layer and the second wiring layer, and bidirectionally supplying a current to the magnetoresistive element.

21. The device according to claim 20, further comprising:
a select transistor connected between the second electrode and the second wiring layer; and
a third wiring layer ON/OFF-controlling the select transistor.
